(19) United States
(12) Patent Application Publication
(10) Pub. No.: US 2026/0015445 A1
(43) Pub. Date: Jan. 15, 2026

(54) COPOLYMER, PIEZOELECTRIC MATERIAL, PIEZOELECTRIC FILM, AND PIEZOELECTRIC ELEMENT

(71) Applicant: TDK Corporation, Tokyo (JP)

(72) Inventor: Junichi HOSHINO, Tokyo (JP)

(73) Assignee: TDK Corporation, Tokyo (JP)

(21) Appl. No.: 18/992,660

(22) PCT Filed: Jun. 2, 2023
(86) PCT No.: PCT/JP2023/020672

§ 371 Date: Jan. 9, 2025

(30) Foreign Application Priority Data
Jul. 20, 2022 (JP) 2022-115444

(51) Int. Cl. C08F 226/06; H10N 30/00; H10N 30/857; H10N 30/87

(52) U.S. Cl. CPC C08F 226/06; H10N 30/704; H10N 30/857; H10N 30/87

(57) ABSTRACT

A copolymer having a structural unit represented by Formula (1) (R¹ is any one selected from the group consisting of a hydrogen atom, a methyl group, a dimethyl group, an ethyl group, an isopropyl group, an isobutyl group, a phenyl group, and a benzyl group, and R² is a hydrogen atom or a methyl group, or R¹ and R² form a benzoxazolidinone skeleton together with an oxazolidinone ring.) and a structural unit represented by Formula (2) is produced.

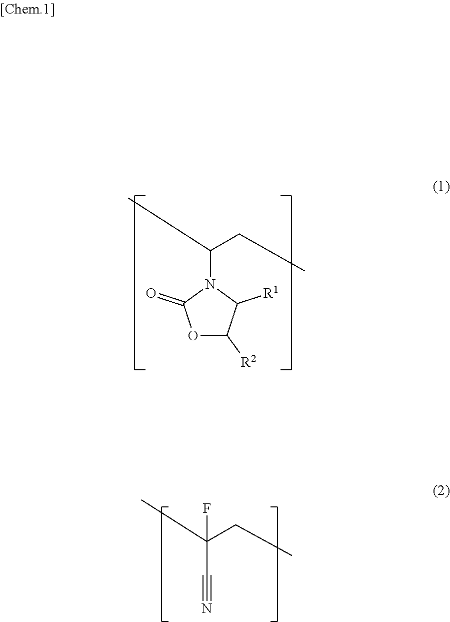

### TECHNICAL FIELD

Priority is claimed on Japanese Patent Application No. 2022-115444, filed Jul. 20, 2022, the content of which is incorporated herein by reference.

The present invention relates to a copolymer, a piezoelectric material, a piezoelectric film, and a piezoelectric element.

### BACKGROUND ART

In recent years, as a piezoelectric material that forms piezoelectric bodies in piezoelectric elements, PZT (PbZrO₃—PbTiO₃-based solid solution), which is a ceramic material, has been in frequent use. However, PZT is a ceramic containing lead and thus has a disadvantage of being brittle. Therefore, there is a demand for a highly flexible material having a low environmental impact as a piezoelectric material.

As a piezoelectric material that meets such a requirement, the use of a polymer piezoelectric material is considered. The polymer piezoelectric material is a ferroelectric polymer, such as polyvinylidene fluoride (PVDF) or a vinylidene fluoride/trifluoroethylene copolymer (P(VDF/TrFE)). However, these ferroelectric polymers have insufficient heat resistance. Therefore, when piezoelectric bodies made of a conventional ferroelectric polymer reach high temperatures, piezoelectric properties are lost, and physical properties, such as the elastic modulus, deteriorate. Therefore, piezoelectric elements having a piezoelectric body made of a conventional ferroelectric polymer can be used in a narrow temperature range.

In addition, as a piezoelectric material, there is an amorphous polymer piezoelectric material that acquires piezoelectricity by being cooled and polarized at temperatures near the glass transition temperature. Amorphous polymers lose piezoelectric properties when reaching temperatures near the glass transition temperature. Therefore, there is a demand for an amorphous polymer piezoelectric material having a high glass transition temperature and a favorable heat resistance.

As an amorphous polymer piezoelectric material having a high glass transition temperature, a vinylidene cyanide/vinyl acetate copolymer is an exemplary example (for example, refer to Patent Document 1). However, for the vinylidene cyanide/vinyl acetate copolymer, there is a need to use vinylidene cyanide that is hard to handle as a raw material monomer. Specifically, vinylidene cyanide easily homopolymerizes due to a trace amount of moisture in the atmosphere. Therefore, polymers for which vinylidene cyanide is used as a raw material monomer significantly vary during production and are hard to use as amorphous polymer piezoelectric materials.

In addition, as a raw material monomer having a nitrile group like vinylidene cyanide, polymers for which 2-fluoroacrylonitrile is used are known (for example, refer to Non Patent Document 1). 2-Fluoroacrylonitrile has favorable stability. However, conventional polymers for which 2-fluoroacrylonitrile is used as a raw material monomer have low glass transition temperatures and insufficient heat resistance.

### Citation List

### Patent Document

Patent Document 1: PCT International Publication No. WO 1991/013922

### Non Patent Document

Non-Patent Document 1: Journal of the Chemical Society of Japan, Chemistry and Industrial Chemistry, 1985, (10), pp. 1862 to 1868

### SUMMARY OF INVENTION

### Technical Problem

Conventionally, there has been a demand for a polymer piezoelectric material from which a piezoelectric film having high heat resistance and high piezoelectric properties can be obtained.

The present invention has been made in consideration of the above-described circumstance, and an object of the present invention is to provide a copolymer that can be used as a piezoelectric material from which a piezoelectric film having high heat resistance and high piezoelectric properties can be obtained.

In addition, another object of the present invention is to provide a piezoelectric material containing the copolymer of the present invention from which a piezoelectric film having high heat resistance and high piezoelectric properties can be obtained.

In addition, still another object of the present invention is to provide a piezoelectric film containing the copolymer of the present invention and having high heat resistance and high piezoelectric properties and a piezoelectric element having the piezoelectric film of the present invention and having high heat resistance and high piezoelectric properties.

### Solution to Problem

In order to achieve the aforementioned objects, the following means is provided.

A copolymer according to one aspect of the present invention is a copolymer having a structural unit represented by following General Formula (1) and a structural unit represented by following Formula (2).

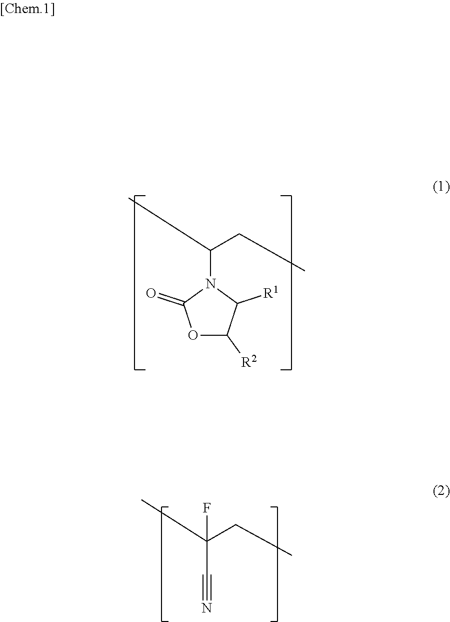

(In the General Formula (1), R¹ is any one selected from the group consisting of a hydrogen atom, a methyl group, a dimethyl group, an ethyl group, an isopropyl group, an isobutyl group, a phenyl group, and a benzyl group, and R² is a hydrogen atom or a methyl group, or R¹ and R² form a benzoxazolidinone skeleton together with an oxazolidinone ring.)

### Advantageous Effects of Invention

The copolymer of the present invention has the structural unit represented by the General Formula (1) and the structural unit represented by the Formula (2). Therefore, the copolymer of the present invention can be used as a piezoelectric material from which a piezoelectric film having high heat resistance and high piezoelectric properties can be obtained.

In addition, a piezoelectric material of the present invention contains the copolymer of the present invention and thus enables a piezoelectric film having high heat resistance and high piezoelectric properties to be obtained.

In addition, a piezoelectric film of the present invention contains the copolymer of the present invention. Therefore, the piezoelectric film of the present invention and a piezoelectric element of the present invention having the piezoelectric film of the present invention are excellent in terms of heat resistance and piezoelectric properties.

### BRIEF DESCRIPTION OF DRAWINGS

FIG. 1 A ¹H-NMR measurement chart of Example 3.

FIG. 2 A ¹⁹F-NMR measurement chart of Example 3.

FIG. 3 A ¹H-NMR measurement chart of Example 8.

FIG. 4 A ¹⁹F-NMR measurement chart of Example 8.

### DESCRIPTION OF EMBODIMENTS

In order to achieve the above-described objects, the present inventors paid attention to a polymer for which a stable monomer having a nitrile group (C—C≡N) is used as a raw material monomer and repeated intensive studies.

As a result, it was found that a copolymer having a structural unit including an oxazolidinone skeleton and a structural unit derived from acrylonitrile becomes a piezoelectric material from which a piezoelectric film having favorable heat resistance and favorable piezoelectric properties can be obtained. The reason therefor is assumed that, in the copolymer, an ordered structure enabling a nitrile group, which is a polar group derived from acrylonitrile, to be formed is disturbed due to the highly polar structural unit including a oxazolidinone skeleton and nitrile groups are less likely to be oriented such that the polarities cancel out each other.

Therefore, the present inventors paid attention to the dipole moment of the copolymer having a structural unit including an oxazolidinone skeleton and a structural unit derived from acrylonitrile and repeated studies to further improve the piezoelectric properties of a piezoelectric film containing the copolymer. However, in this piezoelectric film containing the copolymer, it was difficult to enhance the piezoelectric properties for reasons to be described below.

That is, in order to enhance the piezoelectric properties of the piezoelectric film containing the copolymer, it is desirable to prevent nitrile groups that are contained in the structural unit derived from acrylonitrile in the copolymer from being oriented such that the dipole moments cancel out each other. However, in polymers for which acrylonitrile is used as a raw material monomer, the symmetry of the dipole moment with respect to the main chain direction of the polymer is low. In addition, even when acrylonitrile and a compound having a vinyl group bonded to a nitrogen atom in an oxazolidinone skeleton were copolymerized together, it was not possible to sufficiently suppress the dipole moments of nitrile groups derived from acrylonitrile cancelling out each other. Due to this fact, it was difficult to further enhance the piezoelectric properties in the piezoelectric film containing the copolymer.

Therefore, the present inventors repeated studies regarding a polymer for which a stable monomer having a nitrile group is used as a raw material monomer instead of acrylonitrile, in which the monomer enables a polymer in which the symmetry of the dipole moment with respect to the main chain direction of the polymer is high to be obtained.

As a result, it was found that a copolymer having a specific structural unit including an oxazolidinone skeleton and a structural unit derived from 2-fluoroacrylonitrile is preferable.

That is, in the copolymer having a specific structural unit including an oxazolidinone skeleton and a structural unit derived from 2-fluoroacrylonitrile, since a fluoro group that is contained in the structural unit derived from 2-fluoroacrylonitrile forms an intermolecular hydrogen bond, the interaction between molecules becomes strong. As a result, in piezoelectric films for which this copolymer is used, it is assumed that the heat resistance becomes favorable compared with that in a case where a copolymer having a structural unit derived from acrylonitrile instead of a structural unit derived from 2-fluoroacrylonitrile is used.

In addition, since the copolymer has a nitrile group and a fluoro group that are contained in the structural unit derived from 2-fluoroacrylonitrile, the symmetry of the dipole moment with respect to the main chain direction of the polymer is high. Therefore, in the copolymer, the dipole moments cancelling out each other are suppressed, and a high polarity can be developed. Due to this fact, in piezoelectric films for which the above-described copolymer is used, it is assumed that favorable piezoelectric properties can be obtained compared with a case where the copolymer having a structural unit derived from acrylonitrile instead of a structural unit derived from 2-fluoroacrylonitrile is used.

Furthermore, the present inventors produced the copolymer (polymer) having a specific structural unit including an oxazolidinone skeleton and a structural unit derived from 2-fluoroacrylonitrile, confirmed that the heat resistance thereof was favorable and the piezoelectric properties of a piezoelectric film for which this copolymer was used as a piezoelectric material were favorable, and obtained an idea of the present invention.

In addition, the present inventors studied the use of a compound in which the fluoro group (—F) in 2-fluoroacrylonitrile is a different halogen group (a chloro group (—Cl), a bromo group (—Br), or an iodo group (—I)) as a raw material monomer instead of 2-fluoroacrylonitrile. However, for the compound in which the fluoro group in 2-fluoroacrylonitrile is a different halogen group, the copolymerization with a compound having a vinyl group bonded to a nitrogen atom in an oxazolidinone skeleton was difficult. Therefore, it was not possible to produce a copolymer with a compound having a vinyl group bonded to a nitrogen atom in an oxazolidinone skeleton using a compound in which the fluoro group in 2-fluoroacrylonitrile is a different halogen group instead of 2-fluoroacrylonitrile as a raw material monomer.

The present invention includes the following aspects.

[1] A copolymer having a structural unit represented by following General Formula (1) and a structural unit represented by following Formula (2).

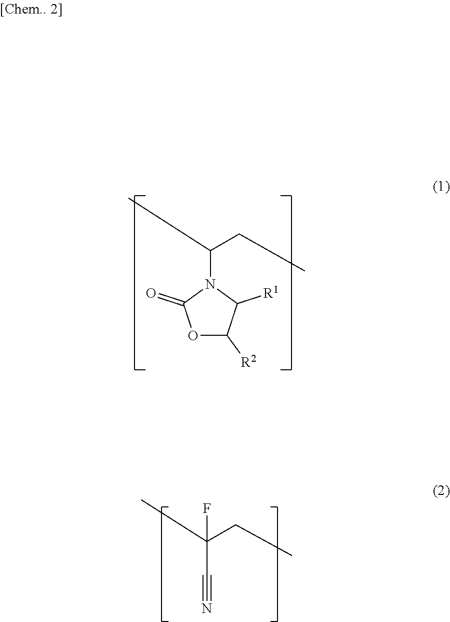

(In the General Formula (1), R¹ is any one selected from the group consisting of a hydrogen atom, a methyl group, a dimethyl group, an ethyl group, an isopropyl group, an isobutyl group, a phenyl group, and a benzyl group, and R² is a hydrogen atom or a methyl group, or R¹ and R² form a benzoxazolidinone skeleton together with an oxazolidinone ring.)

[2] The copolymer according to [1], in which, in the General Formula (1), R¹ is a hydrogen atom, and R² is a hydrogen atom or a methyl group.

[3] The copolymer according to [1] or [2], in which the amount of the structural unit represented by the Formula (2) is 10 to 80 mol %.

[4] A piezoelectric material containing the copolymer according to any one of [1] to [3].

[5] A piezoelectric film containing the copolymer according to any one of [1] to [3].

[6] A piezoelectric element having the piezoelectric film according to [5] and an electrode disposed on each of a first surface and a second surface of the piezoelectric film.

Hereinafter, the copolymer, piezoelectric material, piezoelectric film, and piezoelectric element of the present invention will be described in detail.

### Copolymer

A copolymer (polymer) of the present embodiment has a structural unit represented by General Formula (1) and a structural unit represented by Formula (2).

In the structural unit represented by Formula (1) in the copolymer of the present embodiment, R¹ is any one selected from the group consisting of a hydrogen atom, a methyl group, a dimethyl group, an ethyl group, an isopropyl group, an isobutyl group, a phenyl group, and a benzyl group, and R² is a hydrogen atom or a methyl group. The copolymer of the present embodiment can be easily produced since R¹ and R² in the structural unit represented by Formula (1) are as described above. In addition, the copolymer of the present embodiment can be used as a material for piezoelectric films having favorable heat resistance and favorable piezoelectric properties since R¹ and R² in the structural unit represented by Formula (1) are as described above. R¹ and R² in the structural unit represented by Formula (1) are not polar and thus preferably have small volumes. This is considered to be because the proportion of the volume of polar portions in the entire copolymer relatively increases, which contributes to improvement in in the piezoelectric properties of piezoelectric films for which this copolymer is used. Specifically, it is preferable that R¹ is a hydrogen atom and R² is a hydrogen atom or a methyl group. Furthermore, as is clear from Examples, since the copolymer can be used as a material for piezoelectric films having favorable heat resistance and favorable piezoelectric properties, it is preferable that, particularly, R¹ is a hydrogen atom and R² is a methyl group.

In the structural unit represented by Formula (1), R¹ and R² may form a benzoxazolidinone skeleton together with an oxazolidinone ring. In a case where R¹ and R² in the structural unit represented by Formula (1) in the copolymer of the present embodiment form a benzoxazolidinone skeleton together with an oxazolidinone ring as well, the copolymer can be easily produced and can be used as a material for piezoelectric films having favorable heat resistance and favorable piezoelectric properties.

In the copolymer of the present embodiment, the array order of the structural unit represented by Formula (1) and the structural unit represented by Formula (2), which are repeating units, is not particularly limited. In addition, in the copolymer of the present embodiment, the number of the structural units represented by Formula (1) and the number of the structural units represented by Formula (2) may be the same as or different from each other. Therefore, in the copolymer of the present embodiment, an alternative array portion in which the structural units represented by Formula (1) and the structural units represented by Formula (2) are alternatively arrayed, a random array portion in which the structural units represented by Formula (1) and the structural units represented by Formula (2) are randomly arrayed, and a block array portion having a portion in which the structural units represented by Formula (1) are continuously arrayed and a portion in which the structural units represented by Formula (2) are continuously arrayed may be distributed in arbitrary proportions. The copolymer of the present embodiment preferably includes the alternative array portion since fluoro groups and nitrile groups that are contained in the structural unit represented by Formula (2) are less likely to be oriented such that the polarities cancel out each other, and the copolymer can be used as a piezoelectric material having favorable heat resistance and favorable piezoelectric properties.

In the copolymer of the present embodiment, the amount of the structural unit represented by Formula (1) is preferably 10 to 80 mol %, more preferably 20 to 70 mol %, and still more preferably 30 to 60 mol %. When the amount of the structural unit represented by Formula (1) is 10 mol % or more, the copolymer becomes more favorable in terms of heat resistance. In addition, when the amount of the structural unit represented by Formula (1) is 80 mol % or less, it is possible to prevent piezoelectric films containing the copolymer from becoming hard and brittle due to the amount of the structural unit represented by Formula (1) being too large. In addition, when the amount of the structural unit represented by Formula (1) is 80 mol % or less, it is possible to suppress the insulation resistance of the copolymer being decreased due to the structural unit represented by Formula (1) absorbing moisture.

In the copolymer of the present embodiment, the amount of the structural unit represented by Formula (2) is preferably 10 to 80 mol %, more preferably 20 to 70 mol %, and still more preferably 30 to 60 mol %. When the amount of the structural unit represented by Formula (2) is 10 mol % or more, the copolymer enables flexible piezoelectric films having high insulation resistance to be formed. In addition, when the amount of the structural unit represented by Formula (2) is 80 mol % or less, it becomes easy to secure the amount of the structural unit represented by Formula (1). As a result, the fluoro groups and the nitrile groups that are contained in the structural unit represented by Formula (2) are less likely to be oriented such that the polarities cancel out each other, and the copolymer enables piezoelectric films having more favorable heat resistance and more favorable piezoelectric properties to be formed.

The copolymer of the present embodiment may include one or more different structural units other than the structural unit represented by Formula (1) and the structural unit represented by Formula (2) as necessary. Examples of the different structural units include structural units derived from a well-known monomer or oligomer having a polymerizable unsaturated bond, such as acrylonitrile.

The total amount of the structural unit represented by Formula (1) and the structural unit represented by Formula (2) among the structural units that are contained in the copolymer of the present embodiment is preferably 50 mass % or more and more preferably 80 mass % or more. The total content may be 90 mass % or more, and only the structural unit represented by Formula (1) and the structural unit represented by Formula (2) may be included.

The weight-average molecular weight (Mw) of the copolymer of the present embodiment is preferably 10,000 to 1,000,000. When the weight-average molecular weight (Mw) of the copolymer is 10,000 or higher, the copolymer becomes favorable in terms of a film-forming property, and a piezoelectric film containing the copolymer of the present embodiment can be easily produced. When the weight-average molecular weight (Mw) of the copolymer is 1,000,000 or lower, it is possible to easily dissolve the copolymer in a solvent and to easily produce a piezoelectric film using a coating liquid dissolved in a solvent.

### Method for Producing Copolymer

The copolymer of the present embodiment can be produced by, for example, a method in which radical copolymerization is performed by a well-known method using a compound from which the structural unit represented by Formula (1) is derived, a raw material monomer containing 2-fluoroacrylonitrile, and a polymerization initiator, such as azobisisobutyronitrile.

Polymerization conditions, such as the reaction temperature and the reaction time, at the time of producing the copolymer of the present embodiment can be determined as appropriate depending on the composition of the raw material monomer or the like.

The compound from which the structural unit represented by Formula (1) is derived is a compound having a vinyl group bonded to a nitrogen atom in an oxazolidinone skeleton, in which the oxazolidinone skeleton and an atom that is bonded to a carbon atom in the oxazolidinone skeleton are the same as those in the structural unit represented by Formula (1).

Specific examples of the compound from which the structural unit represented by Formula (1) is derived include N-vinyl-oxazolidinone, N-vinyl-5-methyloxazolidinone, N-vinyl-4-methyloxazolidinone, N-vinyl-4,4-dimethyloxazolidinone, N-vinyl-4-ethyloxazolidinone, N-vinyl-4-propyloxazolidinone, N-vinyl-4-isopropyloxazolidinone, N-vinyl-4-isobutyloxazolidinone, N-vinyl-4-phenyloxazolidinone, N-vinyl-4-benzyloxazolidinone, N-vinyl-2-benzoxazolinone, and the like, and the compound can be determined as appropriate depending on the structure of the copolymer of the present embodiment, which is an intended object.

### Piezoelectric Material

A piezoelectric material of the present embodiment contains the copolymer of the present embodiment. Only one kind of the copolymer of the present embodiment or two or more kinds thereof may be contained in the piezoelectric material of the present embodiment. In addition, the piezoelectric material of the present embodiment may contain one or more kinds of well-known polymers other than the copolymer of the present embodiment together with the copolymer of the present embodiment as necessary.

### Piezoelectric Film

A piezoelectric film of the present embodiment contains the copolymer of the present embodiment.

The piezoelectric film of the present embodiment can be produced by, for example, a method to be described below. A coating liquid is produced by dissolving the piezoelectric material of the present embodiment containing the copolymer of the present embodiment in a well-known solvent, such as N,N-dimethylformamide. Next, the coating liquid is applied onto a releasable substrate in a predetermined thickness to form a coated film. As the substrate, a well-known substrate, such as a substrate made of a resin film such as polyethylene terephthalate (PET), can be used. As a method for applying the coating liquid, a well-known method can be used depending on the coating thickness, the viscosity of the coating liquid, or the like. After that, the coated film is dried, the solvent in the coated film is removed, and a piezoelectric material sheet is produced.

After that, the piezoelectric material sheet is released from the substrate, an electrode made of a well-known conductive material, such as aluminum, is installed on each of a first surface and a second surface of the piezoelectric material sheet, a voltage is applied at a temperature near the glass transition temperature of the piezoelectric material that forms the piezoelectric material sheet, and the piezoelectric material sheet is cooled while the voltage is being applied thereto. Piezoelectricity is thus acquired. A sheet-like piezoelectric film is obtained by the above-described steps.

The electrodes used to acquire piezoelectricity may be used as they are as members for forming a piezoelectric element or may be removed.

### Piezoelectric Element

A piezoelectric element of the present embodiment has the piezoelectric film of the present embodiment and an electrode disposed on the surface of the piezoelectric film. A specific example thereof is a piezoelectric element having a sheet-like piezoelectric film and electrodes disposed on a first surface and a second surface of the piezoelectric film, respectively. As a material of the electrode, a well-known conductive material, such as aluminum, can be used.

The piezoelectric element of the present embodiment can be produced by, for example, providing an electrode on each of a first surface and a second surface of the piezoelectric film by a well-known method, such as a vapor deposition method.

The copolymer of the present embodiment has the structural unit represented by General Formula (1) and the structural unit represented by Formula (2). Therefore, the copolymer of the present embodiment can be used as a piezoelectric material from which a piezoelectric film having high heat resistance and high piezoelectric properties can be obtained.

In addition, the piezoelectric material of the present embodiment contains the copolymer of the present embodiment and thus enables a piezoelectric film having high heat resistance and high piezoelectric properties to be obtained.

In addition, the piezoelectric film of the present embodiment contains the copolymer of the present embodiment. Therefore, the piezoelectric film of the present embodiment and the piezoelectric element of the present embodiment having the piezoelectric film of the present embodiment are excellent in terms of heat resistance and piezoelectric properties.

Hitherto, the embodiment of the present invention has been described in detail, but each configuration, a combination thereof, and the like in each embodiment are simply examples, and the addition, omission, substitution, and other modifications of the configuration are possible within the scope of the gist of the present invention.

### EXAMPLES

### Example 1

0.6 ml (4 mmol) of N-vinyl-oxazolidinone represented by following General Formula (11) and 0.9 ml (12 mmol) of 2-fluoroacrylonitrile were mixed together in a 100 ml Schlenk flask, and 12.4 mg (0.08 mmol) of azobisisobutyronitrile was added thereto, and the components were reacted at 60° C. for two hours. A reaction product was injected into 200 ml of methanol, reprecipitated, filtered, and dried, thereby obtaining 0.6 g of a polymer of Example 1. The yield was 40%.

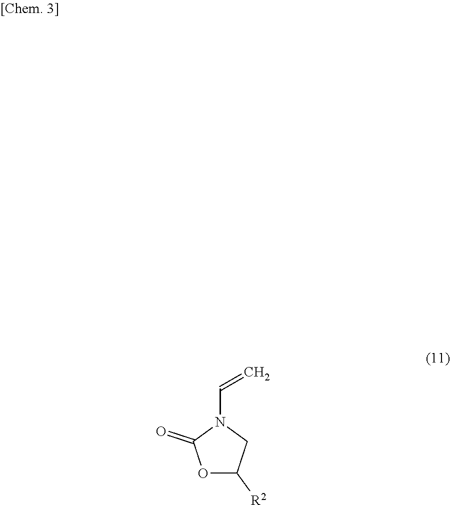

(In General Formula (11), R² is a hydrogen atom.)

On the polymer of Example 1, ¹H-NMR measurement and ¹⁹F-NMR measurement were performed using an NMR (nuclear magnetic resonance) device (trade name JNM-ECA500, manufactured by JEOL Ltd.) and dimethyl sulfoxide d6 (DMSO-d6) as a solvent, thereby specifying the molecular structure.

As a result, it was possible to confirm that the polymer of Example 1 was a copolymer having a structural unit represented by General Formula (1) (R¹ and R² in General Formula (1) were hydrogen atoms) and a structural unit represented by Formula (2).

In addition, composition ratios were calculated from the integral values of individual signals in the ¹H-NMR spectrum and ¹⁹F-NMR spectrum of Example 1. As a result, the amount of the structural unit represented by Formula (2) that was included in the polymer of Example 1 was 76%.

### Example 2

0.9 ml (4 mmol) of N-vinyl-oxazolidinone and 0.4 ml (6 mmol) of 2-fluoroacrylonitrile were mixed together in a 100 ml Schlenk flask, and 7.8 mg (0.05 mmol) of azobisisobutyronitrile was added thereto, and the components were reacted at 60° C. for two hours. A reaction product was injected into 200 ml of methanol, reprecipitated, filtered, and dried, thereby obtaining 0.7 g of a polymer of Example 2. The yield was 62%.

On the polymer of Example 2, ¹H-NMR measurement and ¹⁹F-NMR measurement were performed in the same manner as for the polymer of Example 1, thereby specifying the molecular structure. As a result, it was possible to confirm that the polymer of Example 2 was, similar to the polymer of Example 1, a copolymer having a structural unit represented by General Formula (1) (R¹ and R² in General Formula (1) were hydrogen atoms) and a structural unit represented by Formula (2).

In addition, composition ratios were calculated from the integral values of individual signals in the ¹H-NMR spectrum and ¹⁹F-NMR spectrum of Example 2. As a result, the amount of the structural unit represented by Formula (2) that was included in the polymer of Example 2 was 59%.

### Example 3

0.6 ml (6 mmol) of N-vinyl-oxazolidinone and 0.4 ml (6 mmol) of 2-fluoroacrylonitrile were mixed together in a 100 ml Schlenk flask, and 9.1 mg (0.06 mmol) of azobisisobutyronitrile was added thereto, and the components were reacted at 60° C. for two hours. A reaction product was injected into 200 ml of methanol, reprecipitated, filtered, and dried, thereby obtaining 0.5 g of a polymer of Example 3. The yield was 48%.

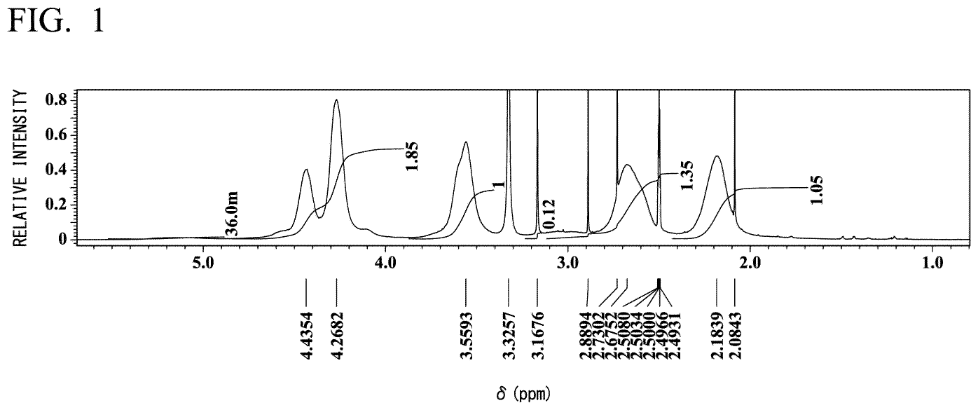

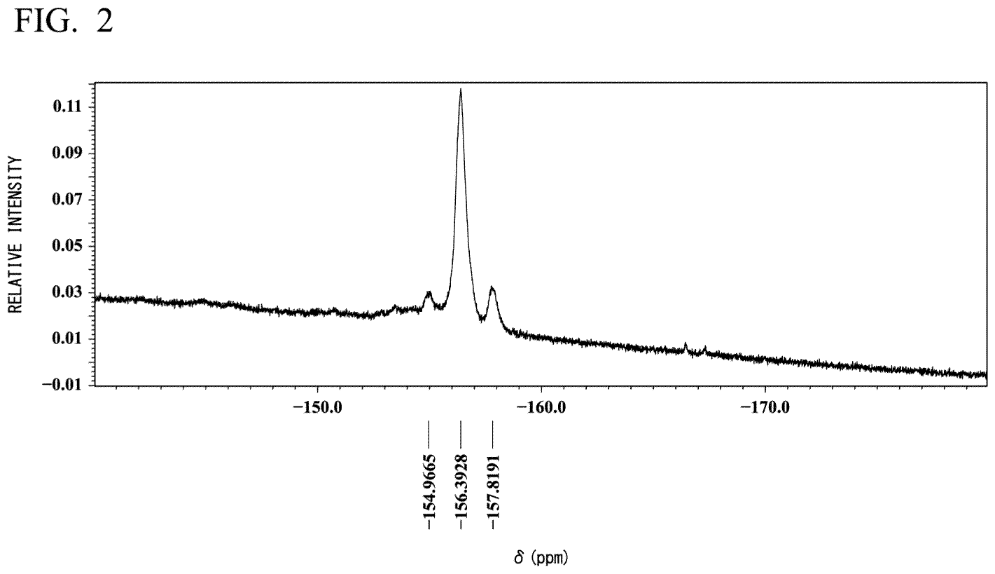

On the polymer of Example 3, ¹H-NMR measurement and ¹⁹F-NMR measurement were performed in the same manner as for the polymer of Example 1, thereby specifying the molecular structure. FIG. 1 is a ¹H-NMR measurement chart of Example 1. FIG. 2 is a ¹⁹F-NMR measurement chart of Example 3.

As a result, it was possible to confirm that the polymer of Example 3 was, similar to the polymer of Example 1, a copolymer having a structural unit represented by General Formula (1) (R¹ and R² in General Formula (1) were hydrogen atoms) and a structural unit represented by Formula (2).

In addition, composition ratios were calculated from the integral values of individual signals in the ¹H-NMR spectrum and ¹⁹F-NMR spectrum of Example 3. As a result, the amount of the structural unit represented by Formula (2) that was included in the polymer of Example 3 was 50%.

### Example 4

0.6 ml (6 mmol) of N-vinyl-oxazolidinone and 0.3 ml (4 mmol) of 2-fluoroacrylonitrile were mixed together in a 100 ml Schlenk flask, and 7.9 mg (0.05 mmol) of azobisisobutyronitrile was added thereto, and the components were reacted at 60° C. for two hours. A reaction product was injected into 200 ml of methanol, reprecipitated, filtered, and dried, thereby obtaining 0.6 g of a polymer of Example 4. The yield was 58%.

On the polymer of Example 4, ¹H-NMR measurement and ¹⁹F-NMR measurement were performed in the same manner as for the polymer of Example 1, thereby specifying the molecular structure. As a result, it was possible to confirm that the polymer of Example 4 was, similar to the polymer of Example 1, a copolymer having a structural unit represented by General Formula (1) (R¹ and R² in General Formula (1) were hydrogen atoms) and a structural unit represented by Formula (2).

In addition, composition ratios were calculated from the integral values of individual signals in the ¹H-NMR spectrum and ¹⁹F-NMR spectrum of Example 4. As a result, the amount of the structural unit represented by Formula (2) that was included in the polymer of Example 4 was 41%.

### Example 5

0.6 ml (12 mmol) of N-vinyl-oxazolidinone and 0.4 ml (6 mmol) of 2-fluoroacrylonitrile were mixed together in a 100 ml Schlenk flask, and 9 mg (0.05 mmol) of azobisisobutyronitrile was added thereto, and the components were reacted at 60° C. for two hours. A reaction product was injected into 200 ml of methanol, reprecipitated, filtered, and dried, thereby obtaining 0.7 g of a polymer of Example 5. The yield was 59%.

On the polymer of Example 5, ¹H-NMR measurement and ¹⁹F-NMR measurement were performed in the same manner as for the polymer of Example 1, thereby specifying the molecular structure. As a result, it was possible to confirm that the polymer of Example 5 was, similar to the polymer of Example 1, a copolymer having a structural unit represented by General Formula (1) (R¹ and R² in General Formula (1) were hydrogen atoms) and a structural unit represented by Formula (2). In addition, composition ratios were calculated from the integral values of individual signals in the ¹H-NMR spectrum and ¹⁹F-NMR spectrum of Example 5. As a result, the amount of the structural unit represented by Formula (2) that was included in the polymer of Example 5 was 25%.

### Example 6

0.9 ml (8 mmol) of N-vinyl-5-methyloxazolidinone (a compound in which R² in General Formula (11) was a methyl group) and 0.3 ml (4 mmol) of 2-fluoroacrylonitrile were mixed together in a 100 ml Schlenk flask, and 10.3 mg (0.06 mmol) of azobisisobutyronitrile was added thereto, and the components were reacted at 60° C. for two hours. A reaction product was injected into 200 ml of methanol, reprecipitated, filtered, and dried, thereby obtaining 0.7 g of a polymer of Example 6. The yield was 56%.

On the polymer of Example 6, ¹H-NMR measurement and ¹⁹F-NMR measurement were performed in the same manner as for the polymer of Example 1, thereby specifying the molecular structure. As a result, it was possible to confirm that the polymer of Example 6 was a copolymer having a structural unit represented by General Formula (1) (R¹ in General Formula (1) was a hydrogen atom, and R² was a methyl group) and a structural unit represented by Formula (2).

In addition, composition ratios were calculated from the integral values of individual signals in the ¹H-NMR spectrum and ¹⁹F-NMR spectrum of Example 6. As a result, the amount of the structural unit represented by Formula (2) that was included in the polymer of Example 6 was 74%.

### Example 7

0.7 ml (6 mmol) of N-vinyl-5-methyloxazolidinone and 0.3 ml (4 mmol) of 2-fluoroacrylonitrile were mixed together in a 100 ml Schlenk flask, and 8.3 mg (0.05 mmol) of azobisisobutyronitrile was added thereto, and the components were reacted at 60° C. for two hours. A reaction product was injected into 200 ml of methanol, reprecipitated, filtered, and dried, thereby obtaining 0.8 g of a polymer of Example 7. The yield was 56%.

On the polymer of Example 7, ¹H-NMR measurement and ¹⁹F-NMR measurement were performed in the same manner as for the polymer of Example 1, thereby specifying the molecular structure. As a result, it was possible to confirm that the polymer of Example 7 was, similar to the polymer of Example 6, a copolymer having a structural unit represented by General Formula (1) (R¹ in General Formula (1) was a hydrogen atom, and R² was a methyl group) and a structural unit represented by Formula (2).

In addition, composition ratios were calculated from the integral values of individual signals in the ¹H-NMR spectrum and ¹⁹F-NMR spectrum of Example 7. As a result, the amount of the structural unit represented by Formula (2) that was included in the polymer of Example 7 was 65%.

### Example 8

0.5 ml (4 mmol) of N-vinyl-5-methyloxazolidinone and 0.3 ml (4 mmol) of 2-fluoroacrylonitrile were mixed together in a 100 ml Schlenk flask, and 6.2 mg (0.04 mmol) of azobisisobutyronitrile was added thereto, and the components were reacted at 60° C. for two hours. A reaction product was injected into 200 ml of methanol, reprecipitated, filtered, and dried, thereby obtaining 0.6 g of a polymer of Example 8. The yield was 76%.

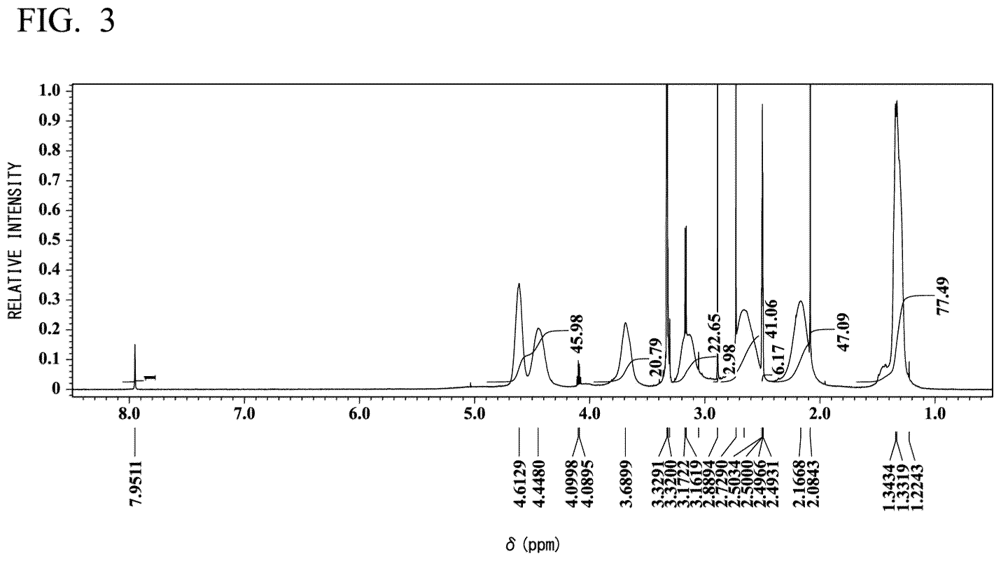

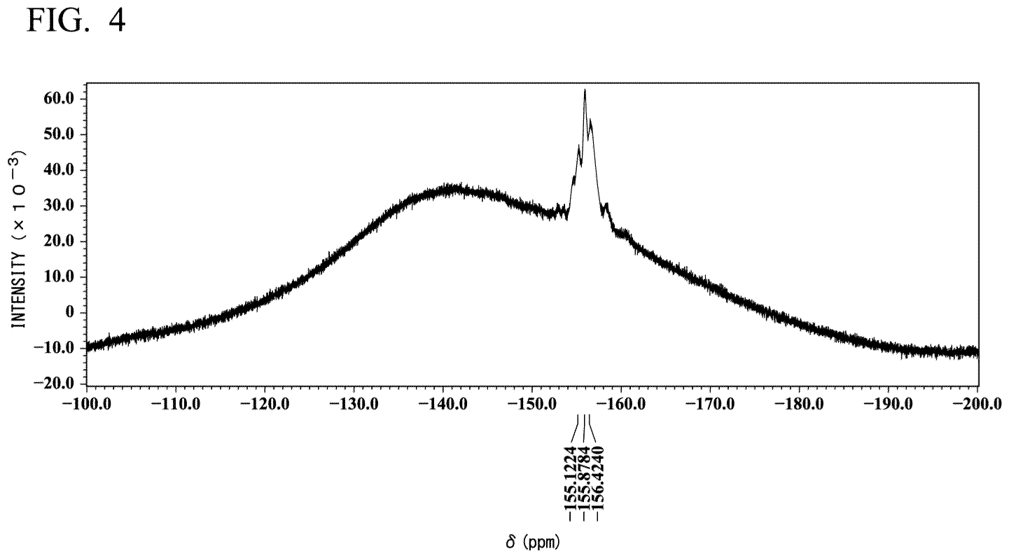

On the polymer of Example 8, ¹H-NMR measurement and ¹⁹F-NMR measurement were performed in the same manner as for the polymer of Example 1, thereby specifying the molecular structure. FIG. 3 is a ¹H-NMR measurement chart of Example 8. FIG. 4 is a ¹⁹F-NMR measurement chart of Example 8.

As a result, it was possible to confirm that the polymer of Example 8 was, similar to the polymer of Example 6, a copolymer having a structural unit represented by General Formula (1) (R¹ in General Formula (1) was a hydrogen atom, and R² was a methyl group) and a structural unit represented by Formula (2).

In addition, composition ratios were calculated from the integral values of individual signals in the ¹H-NMR spectrum and ¹⁹F-NMR spectrum of Example 8. As a result, the amount of the structural unit represented by Formula (2) that was included in the polymer of Example 8 was 53%.

### Example 9

0.4 ml (3 mmol) of N-vinyl-5-methyloxazolidinone and 0.3 ml (4 mmol) of 2-fluoroacrylonitrile were mixed together in a 100 ml Schlenk flask, and 5.5 mg (0.03 mmol) of azobisisobutyronitrile was added thereto, and the components were reacted at 60° C. for two hours. A reaction product was injected into 200 ml of methanol, reprecipitated, filtered, and dried, thereby obtaining 0.4 g of a polymer of Example 9. The yield was 57%.

On the polymer of Example 9, ¹H-NMR measurement and ¹⁹F-NMR measurement were performed in the same manner as for the polymer of Example 1, thereby specifying the molecular structure. As a result, it was possible to confirm that the polymer of Example 9 was, similar to the polymer of Example 6, a copolymer having a structural unit represented by General Formula (1) (R¹ in General Formula (1) was a hydrogen atom, and R² was a methyl group) and a structural unit represented by Formula (2).

In addition, composition ratios were calculated from the integral values of individual signals in the ¹H-NMR spectrum and ¹⁹F-NMR spectrum of Example 9. As a result, the amount of the structural unit represented by Formula (2) that was included in the polymer of Example 9 was 38%.

### Example 10

0.5 ml (4 mmol) of N-vinyl-5-methyloxazolidinone and 0.6 ml (8 mmol) of 2-fluoroacrylonitrile were mixed together in a 100 ml Schlenk flask, and 4.4 mg (0.03 mmol) of azobisisobutyronitrile was added thereto, and the components were reacted at 60° C. for two hours. A reaction product was injected into 200 ml of methanol, reprecipitated, filtered, and dried, thereby obtaining 0.6 g of a polymer of Example 10. The yield was 51%.

On the polymer of Example 10, ¹H-NMR measurement and ¹⁹F-NMR measurement were performed in the same manner as for the polymer of Example 1, thereby specifying the molecular structure. As a result, it was possible to confirm that the polymer of Example 10 was, similar to the polymer of Example 6, a copolymer having a structural unit represented by General Formula (1) (R¹ in General Formula (1) was a hydrogen atom, and R² was a methyl group) and a structural unit represented by Formula (2).

In addition, composition ratios were calculated from the integral values of individual signals in the ¹H-NMR spectrum and ¹⁹F-NMR spectrum of Example 10. As a result, the amount of the structural unit represented by Formula (2) that was included in the polymer of Example 10 was 24%.

### Comparative Example 1

Polyacrylonitrile (trade name 181315, manufactured by Sigma-Aldrich) was used as a polymer of Comparative Example 1.

### Comparative Example 2

Poly(acrylonitrile-CO-methyl acrylate) (trade name 517941, manufactured by Sigma-Aldrich) was used as a polymer of Comparative Example 2.

### Comparative Example 3

0.4 ml (4 mmol) of N-vinyl-oxazolidinone and 1.2 ml (16 mmol) of acrylonitrile were mixed together in a 100 ml Schlenk flask, and 11.5 mg (0.07 mmol) of azobisisobutyronitrile was added thereto, and the components were reacted at 60° C. for two hours. A reaction product was injected into 200 ml of methanol, reprecipitated, filtered, and dried, thereby obtaining 1.1 g of a polymer of Comparative Example 3. The yield was 78%.

On the polymer of Comparative Example 3, ¹H-NMR measurement was performed in the same manner as for the polymer of Example 1, thereby specifying the molecular structure. As a result, it was possible to confirm that the polymer of Comparative Example 3 was a copolymer having a structural unit represented by General Formula (1) (R¹ and R² in General Formula (1) were hydrogen atoms) and a structural unit derived from acrylonitrile.

In addition, composition ratios were calculated from the integral values of individual signals in the ¹H-NMR spectrum of Comparative Example 3. As a result, the amount of the structural unit derived from acrylonitrile that was included in the polymer of Comparative Example 3 was 70%.

### Comparative Example 4

0.4 ml (4 mmol) of N-vinyl-oxazolidinone and 0.6 ml (9 mmol) of acrylonitrile were mixed together in a 100 ml Schlenk flask, and 7.8 mg (0.05 mmol) of azobisisobutyronitrile was added thereto, and the components were reacted at 60° C. for two hours. A reaction product was injected into 200 ml of methanol, reprecipitated, filtered, and dried, thereby obtaining 0.7 g of a polymer of Comparative Example 4. The yield was 70%.

On the polymer of Comparative Example 4, ¹H-NMR measurement was performed in the same manner as for the polymer of Example 1, thereby specifying the molecular structure. As a result, it was possible to confirm that the polymer of Comparative Example 4 was a copolymer having a structural unit represented by General Formula (1) (R¹ and R² in General Formula (1) were hydrogen atoms) and a structural unit derived from acrylonitrile.

In addition, composition ratios were calculated from the integral values of individual signals in the ¹H-NMR spectrum of Comparative Example 4. As a result, the amount of the structural unit derived from acrylonitrile that was included in the polymer of Comparative Example 4 was 59%.

### Comparative Example 5

0.4 ml (4 mmol) of N-vinyl-oxazolidinone and 0.4 ml (7 mmol) of acrylonitrile were mixed together in a 100 ml Schlenk flask, and 6.8 mg (0.04 mmol) of azobisisobutyronitrile was added thereto, and the components were reacted at 60° C. for two hours. A reaction product was injected into 200 ml of methanol, reprecipitated, filtered, and dried, thereby obtaining 0.5 g of a polymer of Comparative Example 5. The yield was 68%.

On the polymer of Comparative Example 5, ¹H-NMR measurement was performed in the same manner as for the polymer of Example 1, thereby specifying the molecular structure. As a result, it was possible to confirm that the polymer of Comparative Example 5 was a copolymer having a structural unit represented by General Formula (1) (R¹ and R² in General Formula (1) were hydrogen atoms) and a structural unit derived from acrylonitrile.

In addition, composition ratios were calculated from the integral values of individual signals in the ¹H-NMR spectrum and of Comparative Example 5. As a result, the amount of the structural unit derived from acrylonitrile that was included in the polymer of Comparative Example 5 was 49%.

### Comparative Example 6

0.4 ml (4 mmol) of N-vinyl-oxazolidinone and 0.3 ml (4 mmol) of acrylonitrile were mixed together in a 100 ml Schlenk flask, and 5.9 mg (0.04 mmol) of azobisisobutyronitrile was added thereto, and the components were reacted at 60° C. for two hours. A reaction product was injected into 200 ml of methanol, reprecipitated, filtered, and dried, thereby obtaining 0.6 g of a polymer of Comparative Example 6. The yield was 87%.

On the polymer of Comparative Example 6, ¹H-NMR measurement was performed in the same manner as for the polymer of Example 1, thereby specifying the molecular structure. As a result, it was possible to confirm that the polymer of Comparative Example 6 was a copolymer having a structural unit represented by General Formula (1) (R¹ and R² in General Formula (1) were hydrogen atoms) and a structural unit derived from acrylonitrile.

In addition, composition ratios were calculated from the integral values of individual signals in the ¹H-NMR spectrum of Comparative Example 6. As a result, the amount of the structural unit derived from acrylonitrile that was included in the polymer of Comparative Example 6 was 24%.

### Comparative Example 7

1.2 ml (12 mmol) of N-vinyl-oxazolidinone and 0.1 ml (2 mmol) of acrylonitrile were mixed together in a 100 ml Schlenk flask, and 0.9 mg (0.03 mmol) of azobisisobutyronitrile was added thereto, and the components were reacted at 60° C. for two hours. A reaction product was injected into 200 ml of methanol, reprecipitated, filtered, and dried, thereby obtaining 4.5 g of a polymer of Comparative Example 7. The yield was 73%.

On the polymer of Comparative Example 7, ¹H-NMR measurement was performed in the same manner as for the polymer of Example 1, thereby specifying the molecular structure. As a result, it was possible to confirm that the polymer of Comparative Example 7 was a copolymer having a structural unit represented by General Formula (1) (R¹ and R² in General Formula (1) were hydrogen atoms) and a structural unit derived from acrylonitrile.

In addition, composition ratios were calculated from the integral values of individual signals in the ¹H-NMR spectrum of Comparative Example 7. As a result, the amount of the structural unit derived from acrylonitrile that was included in the polymer of Comparative Example 7 was 14%.

### Comparative Example 8

0.5 ml (4 mmol) of N-vinyl-5-methyloxazolidinone (a compound in which R² in General Formula (11) was a methyl group) and 1.0 ml (16 mmol) of acrylonitrile were mixed together in a 100 ml Schlenk flask, and 10.7 mg (0.07 mmol) of azobisisobutyronitrile was added thereto, and the components were reacted at 60° C. for two hours. A reaction product was injected into 200 ml of methanol, reprecipitated, filtered, and dried, thereby obtaining 0.9 g of a polymer of Comparative Example 8. The yield was 68%.

On the polymer of Comparative Example 8, ¹H-NMR measurement was performed in the same manner as for the polymer of Example 1, thereby specifying the molecular structure. As a result, it was possible to confirm that the polymer of Comparative Example 8 was a copolymer having a structural unit represented by General Formula (1) (R¹ in General Formula (1) was a hydrogen atom, and R² was a methyl group) and a structural unit derived from acrylonitrile.

In addition, composition ratios were calculated from the integral values of individual signals in the ¹H-NMR spectrum of Comparative Example 8. As a result, the amount of the structural unit derived from acrylonitrile that was included in the polymer of Comparative Example 8 was 76%.

### Comparative Example 9

0.9 ml (8 mmol) of N-vinyl-5-methyloxazolidinone and 1.0 ml (16 mmol) of acrylonitrile were mixed together in a 100 ml Schlenk flask, and 9.8 mg (0.05 mmol) of azobisisobutyronitrile was added thereto, and the components were reacted at 60° C. for two hours. A reaction product was injected into 200 ml of methanol, reprecipitated, filtered, and dried, thereby obtaining 1.2 g of a polymer of Comparative Example 9. The yield was 69%.

On the polymer of Comparative Example 9, ¹H-NMR measurement was performed in the same manner as for the polymer of Example 1, thereby specifying the molecular structure. As a result, it was possible to confirm that the polymer of Comparative Example 9 was a copolymer having a structural unit represented by General Formula (1) (R¹ in General Formula (1) was a hydrogen atom, and R² was a methyl group) and a structural unit derived from acrylonitrile.

In addition, composition ratios were calculated from the integral values of individual signals in the ¹H-NMR spectrum of Comparative Example 9. As a result, the amount of the structural unit derived from acrylonitrile that was included in the polymer of Comparative Example 9 was 57%.

### Comparative Example 10

1.4 ml (12 mmol) of N-vinyl-5-methyloxazolidinone and 1.0 ml (16 mmol) of acrylonitrile were mixed together in a 100 ml Schlenk flask, and 10.8 mg (0.07 mmol) of azobisisobutyronitrile was added thereto, and the components were reacted at 60° C. for two hours. A reaction product was injected into 200 ml of methanol, reprecipitated, filtered, and dried, thereby obtaining 1.5 g of a polymer of Comparative Example 10. The yield was 67%.

On the polymer of Comparative Example 10, ¹H-NMR measurement was performed in the same manner as for the polymer of Example 1, thereby specifying the molecular structure. As a result, it was possible to confirm that the polymer of Comparative Example 10 was a copolymer having a structural unit represented by General Formula (1) (R¹ in General Formula (1) was a hydrogen atom, and R² was a methyl group) and a structural unit derived from acrylonitrile. In addition, composition ratios were calculated from the integral values of individual signals in the ¹H-NMR spectrum of Comparative Example 10. As a result, the amount of the structural unit derived from acrylonitrile that was included in the polymer of Comparative Example 10 was 44%.

### Comparative Example 11

1.4 ml (12 mmol) of N-vinyl-5-methyloxazolidinone and 0.8 ml (12 mmol) of acrylonitrile were mixed together in a 100 ml Schlenk flask, and 9.1 mg (0.06 mmol) of azobisisobutyronitrile was added thereto, and the components were reacted at 60° C. for two hours. A reaction product was injected into 200 ml of methanol, reprecipitated, filtered, and dried, thereby obtaining 1.3 g of a polymer of Comparative Example 11. The yield was 60%.

On the polymer of Comparative Example 11, ¹H-NMR measurement was performed in the same manner as for the polymer of Example 1, thereby specifying the molecular structure. As a result, it was possible to confirm that the polymer of Comparative Example 11 was a copolymer having a structural unit represented by General Formula (1) (R¹ in General Formula (1) was a hydrogen atom, and R² was a methyl group) and a structural unit derived from acrylonitrile. In addition, composition ratios were calculated from the integral values of individual signals in the ¹H-NMR spectrum of Comparative Example 11. As a result, the amount of the structural unit derived from acrylonitrile that was included in the polymer of Comparative Example 11 was 28%.

### Comparative Example 12

1.4 ml (12 mmol) of N-vinyl-5-methyloxazolidinone and 0.4 ml (6 mmol) of acrylonitrile were mixed together in a 100 ml Schlenk flask, and 14.8 mg (0.09 mmol) of azobisisobutyronitrile was added thereto, and the components were reacted at 60° C. for two hours. A reaction product was injected into 200 ml of methanol, reprecipitated, filtered, and dried, thereby obtaining 1.1 g of a polymer of Comparative Example 12. The yield was 60%.

On the polymer of Comparative Example 12, ¹H-NMR measurement was performed in the same manner as for the polymer of Example 1, thereby specifying the molecular structure. As a result, it was possible to confirm that the polymer of Comparative Example 12 was a copolymer having a structural unit represented by General Formula (1) (R¹ in General Formula (1) was a hydrogen atom, and R² was a methyl group) and a structural unit derived from acrylonitrile.

In addition, composition ratios were calculated from the integral values of individual signals in the ¹H-NMR spectrum of Comparative Example 12. As a result, the amount of the structural unit derived from acrylonitrile that was included in the polymer of Comparative Example 12 was 13%.

### Comparative Example 13

0.7 ml (8 mmol) of N-vinyl-oxazolidinone and 0.6 ml (8 mmol) of 2-chloroacrylonitrile were mixed together in a 100 ml Schlenk flask, and 12.2 mg (0.07 mmol) of azobisisobutyronitrile was added thereto, and the components were reacted at 60° C. for two hours. However, 2-chloroacrylonitrile decomposed during the reaction, and a polymer could not be obtained.

### Comparative Example 14

0.9 ml (8 mmol) of N-vinyl-5-methyloxazolidinone (a compound in which R² in General Formula (11) was a methyl group) and 0.6 ml (8 mmol) of 2-chloroacrylonitrile were mixed together in a 100 ml Schlenk flask, and 13.5 mg (0.08 mmol) of azobisisobutyronitrile was added thereto, and the components were reacted at 60° C. for two hours. However, 2-chloroacrylonitrile decomposed during the reaction, and a polymer could not be obtained.

For each of Example 1 to Example 10 and Comparative Example 3 to Comparative Example 14, the kind of R² in the structural unit represented by General Formula (1) that was included in the polymer obtained after synthesis, the name of a monomer having a nitrile group that was used for the synthesis, and the amount of the nitrile group that is contained in the polymer obtained after the synthesis (the amount of the structural unit represented by Formula (2)) are shown in Table 1.

In addition, each of the names of the compounds for the polymers of Comparative Example 1 and Comparative Example 2 is shown in Table 1.

TABLE 1

| | R² in structural unit represented by | Monomer having nitrile | Amount of nitrile | Glass transition | |
|---|---|---|---|---|---|
| | General Formula (1) or polymer name | group | group (mol %) | temperature (° C.) | d₃₃ (pC/N) |
| Example 1 | —H | 2-Fluoroacrylonitrile | 76 | 131 | 4.8 |
| Example 2 | —H | 2-Fluoroacrylonitrile | 59 | 147 | 6.2 |
| Example 3 | —H | 2-Fluoroacrylonitrile | 50 | 156 | 6.4 |
| Example 4 | —H | 2-Fluoroacrylonitrile | 41 | 166 | 5.5 |
| Example 5 | —H | 2-Fluoroacrylonitrile | 25 | 182 | 4.3 |
| Example 6 | —CH₃ | 2-Fluoroacrylonitrile | 74 | 136 | 6.1 |
| Example 7 | —CH₃ | 2-Fluoroacrylonitrile | 65 | 150 | 6.7 |
| Example 8 | —CH₃ | 2-Fluoroacrylonitrile | 53 | 166 | 7.6 |
| Example 9 | —CH₃ | 2-Fluoroacrylonitrile | 38 | 179 | 7.2 |
| Example 10 | —CH₃ | 2-Fluoroacrylonitrile | 24 | 186 | 6.5 |
| Comparative Example 1 | Polyacrylonitrile | — | 100 | 98 | 0.8 |
| Comparative Example 2 | Poly(acrylonitrile-co-methylacrylate) | — | 96 | 97 | 0.7 |
| Comparative Example 3 | —H | Acrylonitrile | 70 | 132 | 1.7 |
| Comparative Example 4 | —H | Acrylonitrile | 59 | 137 | 3.0 |
| Comparative Example 5 | —H | Acrylonitrile | 49 | 140 | 3.2 |
| Comparative Example 6 | —H | Acrylonitrile | 24 | 151 | 2.6 |
| Comparative Example 7 | —H | Acrylonitrile | 14 | 160 | 1.6 |
| Comparative Example 8 | —CH₃ | Acrylonitrile | 76 | 138 | 2.2 |
| Comparative Example 9 | —CH₃ | Acrylonitrile | 57 | 155 | 3.6 |
| Comparative Example 10 | —CH₃ | Acrylonitrile | 44 | 159 | 3.9 |
| Comparative Example 11 | —CH₃ | Acrylonitrile | 28 | 174 | 3.5 |
| Comparative Example 12 | —CH₃ | Acrylonitrile | 13 | 184 | 2.9 |

| | | | | |
|---|---|---|---|---|
| Comparative Example 13 | —H | 2-Fluoroacrylonitrile | — | Decompose during polymerization |
| Comparative Example 14 | —CH₃ | 2-Fluoroacrylonitrile | — | Decompose during polymerization |

For each of the polymers of Example 1 to Example 10 and Comparative Example 1 to Comparative Example 12, the glass transition temperature (Tg) was measured by a method to be described below. The results are shown in Table 1.

### Method for Measuring Glass Transition Temperature (Tg)

A heating and cooling operation of heating the polymer from 30° C. to 200° C. at a heating rate of 20° C./minute, cooling the polymer from 200° C. to 30° C. at a cooling rate of 40° C./minute, and heating the polymer from 30° C. to 200° C. at a heating rate of 20° C./minute in a nitrogen atmosphere was performed using a high-sensitivity differential scanning calorimeter (trade name, DSC6200, manufactured by Seiko Instruments Inc.), and the inflection point at the time of the second heating was obtained and regarded as the glass transition temperature (Tg).

In addition, a piezoelectric film was produced by a method to be described below using each of the polymers of Example 1 to Example 10 and Comparative Example 1 to Comparative Example 12 as a piezoelectric material, and the piezoelectric constant d₃₃ was measured. The results are shown in Table 1.

### Production of Piezoelectric Film

The piezoelectric material was dissolved in N,N-dimethylformamide, which was a solvent, to produce 20 mass % of a polymer solution (coating liquid). The obtained polymer solution was applied onto a PET film (trade name, LUMIRROR (registered trademark), manufactured by Toray Industries, Inc.), which was a substrate, such that the dried thickness reached 50 pm to form a coated film. After that, the coated film formed on the PET film was dried at 120° C. for six hours on a hot plate to remove the solvent in the coated film, thereby obtaining a piezoelectric material sheet.

The obtained piezoelectric material sheet was released from the PET film, and an electrode made of aluminum was provided on each of a first surface and a second surface of the piezoelectric material sheet by a vapor deposition method. After that, a high voltage power supply HARB-20R60 (manufactured by Matsusada Precision Inc.) and the electrodes of the piezoelectric material sheet were electrically connected together and held at 140° C. for 15 minutes in a state where an electric field of 100 MV/m was applied thereto. After that, the piezoelectric material sheet was slowly cooled to room temperature under the application of the voltage, and a polling process was performed thereon, thereby obtaining a sheet-like piezoelectric film.

### Method for Measuring Piezoelectric Constant d₃₃

The piezoelectric film was mounted in a measuring instrument using a pin having a diameter of 1.5 mm at the front end as a sample-fixing jig. As the measuring instrument of the piezoelectric constant d₃₃, a PiezoMeter System PM200 manufactured by Piezotest Pte Ltd. was used.

The actual measurement value of the piezoelectric constant d₃₃ becomes a positive value or a negative value depending on whether the surface of the piezoelectric film that is measured is a front surface or a rear surface. In the present specification, the absolute value of the actual measurement value was used as the value of the piezoelectric constant d₃₃.

As shown in Table 1, it was possible to confirm that the polymers of Example 1 to Example 10 had high glass transition temperatures (Tg) and favorable heat resistance compared with the polymers of Comparative Example 1 and Comparative Example 2.

In addition, all of the polymers of Example 1 to Example 10 had sufficiently high glass transition temperatures (Tg) and favorable heat resistance.

As shown in Table 1, the piezoelectric films of Example 1 to Example 10 containing the polymers of Example 1 to Example 10 had high piezoelectric constants d₃₃ and favorable piezoelectric properties compared with the piezoelectric film of Comparative Example 1 containing the polymer of Comparative Example 1 and the piezoelectric film of Comparative Example 2 containing the polymer of Comparative Example 2.

In addition, all of the piezoelectric films containing the polymers of Example 1 to Example 10 had high piezoelectric constants d₃₃ and favorable piezoelectric properties compared with the piezoelectric films containing the polymers of Comparative Example 3 to Comparative Example 12.

Particularly, the piezoelectric films of Examples 3 to 5 and Examples 8 and 9 containing a polymer in which the amount of the structural unit represented by Formula (2) was 30 to 60 mol % had high piezoelectric constants d₃₃ and favorable piezoelectric properties compared with the piezoelectric films containing a polymer in which R² in the structural unit represented by Formula (1) was the same and the amount of the structural unit represented by Formula (2) was less than 30 mol %.

### Industrial Applicability

It becomes possible to provide a piezoelectric material from which a piezoelectric film having high heat resistance and high piezoelectric properties can be obtained.

It is possible to provide a piezoelectric film having high heat resistance and high piezoelectric properties.

It is possible to provide a piezoelectric element including a piezoelectric film having excellent heat resistance and excellent piezoelectric properties.

1. A copolymer comprising:
a structural unit represented by following General Formula (1); and
a structural unit represented by following Formula (2), 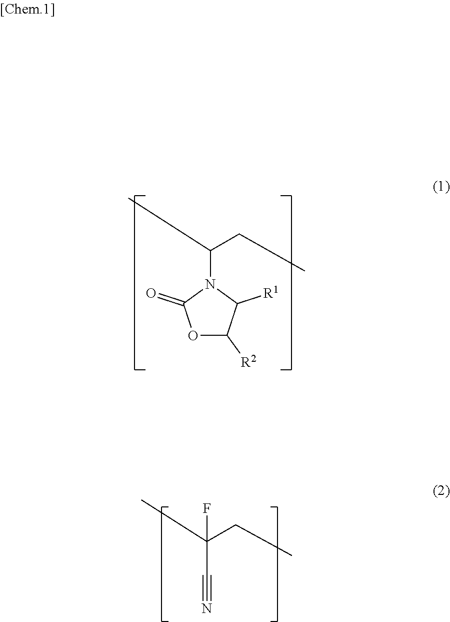
(in the General Formula (1), R¹ is any one selected from the group consisting of a hydrogen atom, a methyl group, a dimethyl group, an ethyl group, an isopropyl group, an isobutyl group, a phenyl group, and a benzyl group, and R² is a hydrogen atom or a methyl group, or R¹ and R² form a benzoxazolidinone skeleton together with an oxazolidinone ring).

2. The copolymer according to claim 2,
wherein, in the General Formula (1), R¹ is a hydrogen atom, and R² is a hydrogen atom or a methyl group.

3. The copolymer according to claim 1,
wherein an amount of the structural unit represented by the Formula (2) is 10 to 80 mol %.

4. A piezoelectric material comprising:
the copolymer according to claim 1.

5. A piezoelectric film comprising:
the copolymer according to claim 1.

6. A piezoelectric element comprising:
the piezoelectric film according to claim 5; and
an electrode disposed on each of a first surface and a second surface of the piezoelectric film.
